(19) United States
(12) Patent Application Publication
(10) Pub. No.: US 2006/0125080 A1
(43) Pub. Date: Jun. 15, 2006

(54) Semiconductor package structure and method for fabricating the same

(75) Inventor: Shih-Ping Hsu, Hsin-chu (TW)

Correspondence Address: Mr. William F. Nixon;SQUIRE SANDERS & DEMPSEY LLP, 14th Floor, 8000 Towers Crescent Drive, Tysons Corner, VA, 22182-2700, US

(73) Assignee: Phoenix Precision Technology Corporation

(21) Appl. No.: 11/055,116

(22) Filed: Feb. 11, 2005

(30) Foreign Application Priority Data
Dec. 9, 2004 (TW) 093138072

(51) Int. Cl. H01L 23/48

(52) U.S. Cl. 257/693

(57) ABSTRACT

A semiconductor package structure and a method for fabricating the same are proposed. A carrier having at least one cavity is provided. At least one semiconductor chip having electrode pads is mounted in the cavity. A dielectric layer is applied on the carrier and the chip, and has vias for exposing the electrode pads of the chip. A circuit layer and conductive structures are formed on the dielectric layer and in the vias, wherein the conductive structures are electrically connected to the electrode pads of the chip. A conductive adhesive layer having conductive adhesive posts and a circuit board having conductive pads thereon are provided. The circuit board is mounted on the carrier via the conductive adhesive layer. The conductive pads of the circuit board are electrically connected to the circuit layer by the conductive adhesive posts and are further electrically connected to the electrode pads of the chip.

### FIELD OF THE INVENTION

The present invention relates to semiconductor package structures and methods for fabricating the same, and more particularly, to a package structure capable of integrating a carrier, a semiconductor chip and a circuit board therein, and a method for fabricating the package structure.

### BACKGROUND OF THE INVENTION

Along with the development of semiconductor packaging technology, different types of semiconductor devices have been produced. Ball Grid Array (BGA) is an advanced semiconductor packaging technique, which is characterized in the use of a substrate for mounting a semiconductor chip on a front side thereof, and implanting a grid array of solder balls on a back side thereof using a self-alignment technique. This allows more input/output (I/O) connections to be accommodated on the same unit area of a chip carrier e.g. the substrate so as to satisfy the requirement of high integration for the semiconductor chip, and the entire package unit can be electrically connected to an external printed circuit board via the solder balls. Common IC (integrated circuit) package substrates include a plastic ball grid array (PBGA) substrate and a flip chip ball grid array (FCBGA) substrate.

For a flip-chip semiconductor package, corresponding conductive units (such as metal bumps and pre-solder bumps) need to be respectively formed on a semiconductor chip and a corresponding circuit board. This not only increases the fabrication cost but also may raise the possibility of affecting reliability in fabrication.

Moreover, during general fabrication processes of a semiconductor device, firstly, a suitable chip carrier for the semiconductor device is fabricated by a chip carrier manufacturer (such as a circuit board manufacturer). Then, the chip carrier is transferred to a semiconductor packaging manufacturer where the chip carrier is subjected to die-bonding, molding and ball-implanting processes to eventually form the semiconductor device with desirable electronic functions for a client. These fabrication processes of the semiconductor device involve different manufacturers (including the chip carrier manufacturer and the semiconductor packaging manufacturer), which are complicated in practice and have difficulty in interface integration. Moreover, if the client wishes to alter the functional design of the semiconductor device, this would involve further complicated changes and interface integration, thereby not providing flexibility in alteration and not satisfying the economical concern.

Referring to FIG. 1, in light of the foregoing drawbacks, there has been proposed to directly integrate a semiconductor chip with a circuit board. Such integrated structure comprises a carrier 11 having a cavity 110; a semiconductor chip 13 received in the cavity 110 of the carrier 11; and a circuit build-up structure 14 formed on the semiconductor chip 13 and the carrier 11, wherein the circuit build-up structure 14 is formed with conductive vias 141 for being electrically connected to the semiconductor chip 13.

The semiconductor chip 13 can be mounted in the cavity 110 of the carrier 11 via a thermally conductive adhesive layer 12, such that heat generated by the semiconductor chip 13 during operation can be dissipated via a thermally conductive path formed by the thermally conductive adhesive layer 12 and the carrier 11.

The circuit build-up structure 14 is formed on the semiconductor chip 13 and the carrier 11 by a build-up technique. The circuit build-up structure 14 comprises a dielectric layer 140 applied on the semiconductor chip 13 and the carrier 11, and a circuit layer 142 disposed on the dielectric layer 140, wherein the conductive vias 141 are formed in the dielectric layer 140 and electrically connected to electrode pads 130 on an active surface of the semiconductor chip 13.

Although the above circuit board structure integrated with the semiconductor chip can eliminate the foregoing prior-art drawbacks, it requires multiple times of a circuit build-up process to be performed on the semiconductor chip 13 and the carrier 11 to form the circuit build-up structure 14 and fabricate such circuit board structure. As a result, the time required for fabrication is increased, and the fabrication yield is reduced by necessarily performing multiple times of the build-up process. Moreover, during fabrication of the circuit build-up structure, the same build-up process is repeated to laminate build-up layers from interior to exterior. However, if any of the build-up layers is defective, it cannot be detected until the final build-up structure being tested. This thereby causes a serious loss and makes mass production time-ineffective and cost-ineffective to implement, such that the mass production would be adversely affected as a consequence.

### SUMMARY OF THE INVENTION

In light of the above drawbacks in the prior art, a primary objective of the present invention is to provide a semiconductor package structure and a method for fabricating the same, which can integrate chip carrier manufacture and a chip packaging technique so as to provide more flexibility to satisfy clients' requirements and simplify the semiconductor fabrication processes and an interface integration problem.

Another objective of the present invention is to provide a semiconductor package structure and a method for fabricating the same, so as to further simplify an integrated form of a circuit board and a semiconductor chip and provide improved electrical performances.

A further objective of the present invention is to provide a semiconductor package structure and a method for fabricating the same, which can simplify the fabrication processes, shorten the time required for fabrication, and reduce defective products and a loss to the yield, as well as realize mass production.

In accordance with the above and other objectives, the present invention proposes a method for fabricating a semiconductor package structure, comprising the steps of: providing a carrier having at least one cavity formed on a surface thereof, and mounting at least one semiconductor chip in the cavity of the carrier, wherein a plurality of electrode pads are formed on an active surface of the semiconductor chip; applying a dielectric layer on the carrier and the semiconductor chip, wherein the dielectric layer is formed with a plurality of vias therein for exposing the electrode pads of the semiconductor chip; forming a circuit layer and a plurality of conductive structures on a surface of the dielectric layer and in the vias, wherein the conductive structures are electrically connected to the electrode pads of the semiconductor chip; providing a conductive adhesive layer having a plurality of conductive adhesive posts, and a circuit board having a plurality of conductive pads on a surface thereof, and mounting the circuit board on the dielectric layer via the conductive adhesive layer, such that the conductive pads of the circuit board are electrically connected to the circuit layer of the dielectric layer by the conductive adhesive posts of the conductive adhesive layer and are further electrically connected to the electrode pads of the semiconductor chip, so as to form a package structure integrated with the carrier, the semiconductor chip and the circuit board therein.

The dielectric layer is formed on the carrier and the semiconductor chip, and the material of the dielectric layer can fill into the gap between the cavity of the carrier and the semiconductor chip. The circuit layer is formed on the dielectric layer, and the plurality of conductive structures are formed in the vias of the dielectric layer, such that the circuit layer can be electrically connected to the electrode pads on the active surface of the semiconductor chip by the conductive structures. Moreover, the circuit board can be a double-layer or multi-layer circuit board.

The present invention also proposes a semiconductor package structure fabricated by the foregoing method, comprising: a carrier having a cavity; at least one semiconductor chip having a plurality of electrode pads and mounted in the cavity of the carrier; a dielectric layer formed on the carrier and the semiconductor chip, wherein a plurality of vias are formed in the dielectric layer, and a circuit layer and a plurality of conductive structures are formed on a surface of the dielectric layer and in the vias, such that the circuit layer is electrically connected to the electrode pads of the semiconductor chip by the conductive structures; a conductive adhesive layer having a plurality of conductive adhesive posts and formed on the dielectric layer, wherein the conductive adhesive posts are electrically connected to the circuit layer of the dielectric layer; and a circuit board having a plurality of conductive pads on a surface thereof and formed on the conductive adhesive layer, wherein the conductive pads of the circuit board are electrically connected to the conductive adhesive posts of the conductive adhesive layer, such that the circuit board is electrically connected to the electrode pads of the semiconductor chip by the conductive adhesive posts and the circuit layer and conductive structures of the dielectric layer.

The circuit board can be a double-layer or multi-layer circuit board, and is subsequently mounted on the carrier incorporated with the semiconductor chip by means of the conductive adhesive layer and the dielectric layer. This can eliminate the prior-art drawbacks such as complex fabrication processes, increased fabrication cost, long fabrication time and low reliability for a conventional semiconductor package. Further, the above arrangement can also avoid a loss to the cost and material caused by an overall package being found defective due to any defective build-up layer being formed during performing subsequent build-up processes on the carrier mounted with the semiconductor chip. Moreover, the circuit board can be preformed and in advance tested, which can prevent a loss to the cost and material caused by a defective product being examined and detected only after integration with the chip is complete, such that the fabrication rate can be increased to facilitate mass production.

Therefore, by the semiconductor package structure and the method for fabricating the same proposed in the present invention, at least one semiconductor chip having a plurality of electrode pads on a surface thereof is received in a cavity of a carrier, such that an overall thickness of the semiconductor package can be reduced to satisfy the requirement of profile miniaturization. Then, a dielectric layer is disposed on the carrier and the semiconductor chip, and is formed with a plurality of vias therein. A circuit layer and a plurality of conductive structure are formed on a surface of the dielectric layer and in the vias, and are electrically connected to the electrode pads of the semiconductor chip. Subsequently, a conductive adhesive layer and a circuit board having a plurality of conductive pads formed on a surface thereof are mounted on the dielectric layer. The conductive pads of the circuit board are electrically connected to the circuit layer and the conductive structures of the dielectric layer by conductive adhesive posts of the conductive adhesive layer, and are further electrically connected to the electrode pads of the semiconductor chip, so as to form a semiconductor package structure integrated with the carrier, the semiconductor chip and the circuit board therein. This combines chip carrier manufacture and a semiconductor packaging technique, and provides more flexibility to satisfy clients' requirements, as well as simplifies the semiconductor fabrication processes and an interface integration problem. Further in the present invention, electrical performances of the product can be improved, the fabrication processes can be simplified, and a loss to the yield can be reduced, thereby overcoming the drawbacks in the prior art.

### BRIEF DESCRIPTION OF THE DRAWINGS

The present invention can be more fully understood by reading the following detailed description of the preferred embodiments, with reference made to the accompanying drawings, wherein:

FIG. 1 (PRIOR ART) is a cross-sectional view of a conventional circuit board structure integrated with a semiconductor chip; and

FIGS. 2A to 2J are cross-sectional schematic diagrams showing procedural steps of a method for fabricating a semiconductor package structure according to the present invention.

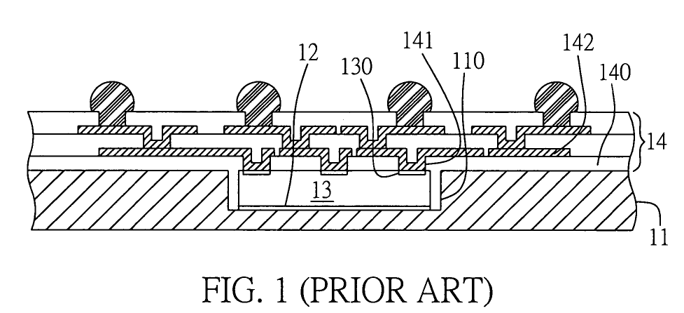

### DETAILED DESCRIPTION OF THE PREFERRED EMBODIMENTS

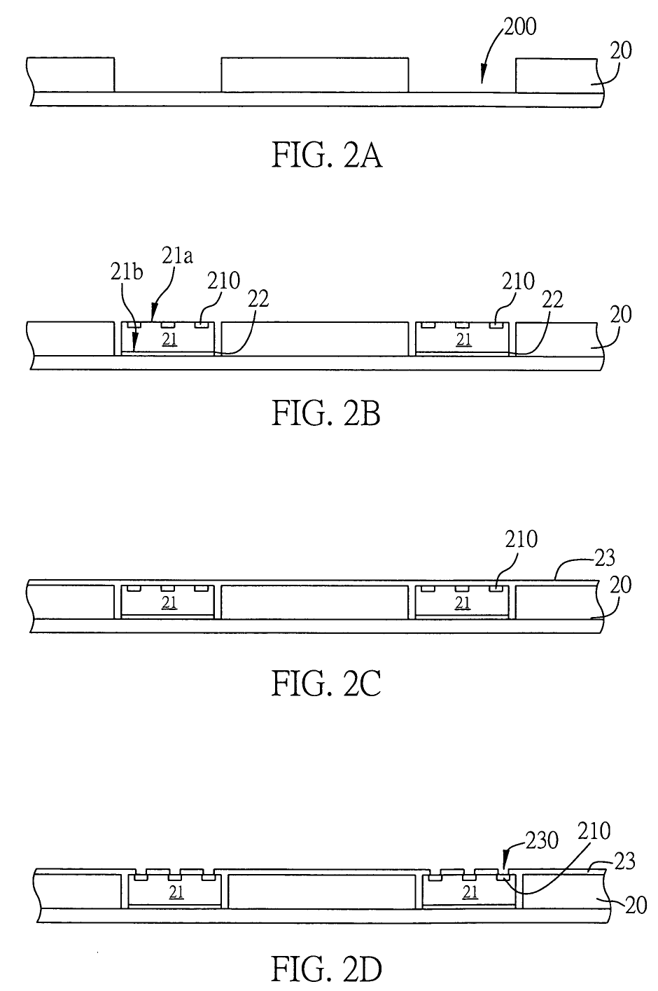

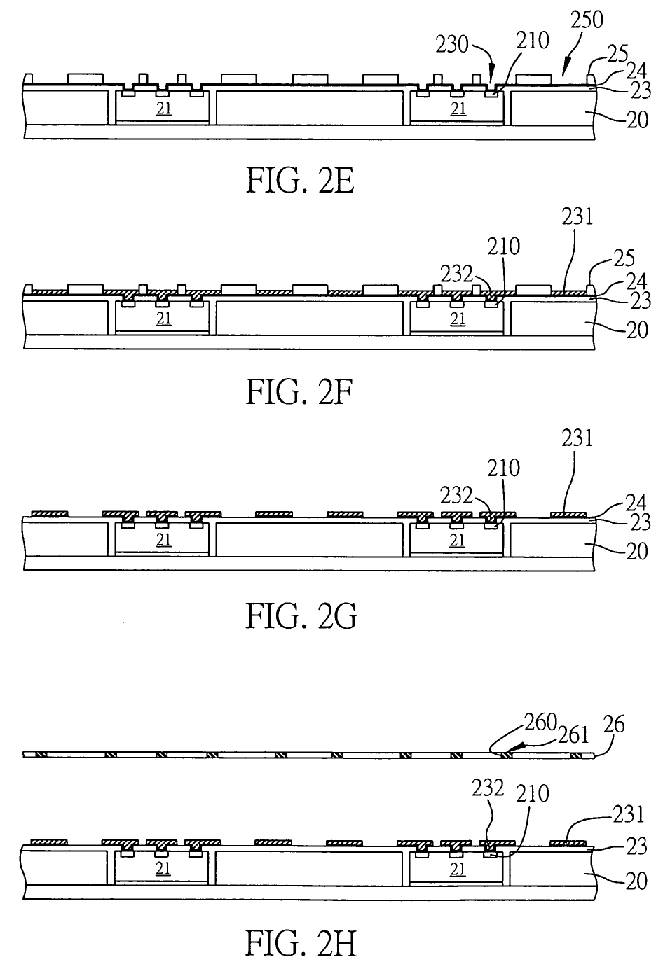

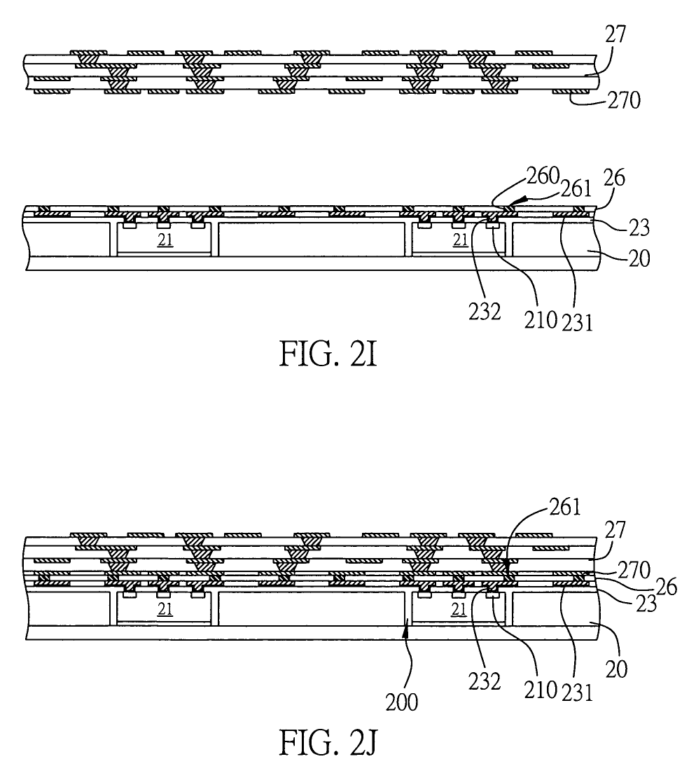

FIGS. 2A to 2J are cross-sectional schematic diagrams showing procedural steps of a method for fabricating a semiconductor package structure according to the present invention.

Referring to FIG. 2A, firstly, a carrier 20 having at least one cavity 200 is provided, such that at least one passive or active component such as semiconductor chip can be subsequently mounted in the cavity 200. The carrier 20 can be a metal plate, a ceramic plate or a circuit board. Alternatively, the carrier 20 having the cavity 200 can also be a combined structure of a heat sink and a circuit board with a cavity.

Referring to FIG. 2B, a non-active surface 21b of at least one semiconductor chip 21 is mounted in the cavity 200 of the carrier 20 via an adhesive layer. An active surface 21a of the semiconductor chip 21 is formed with a plurality of electrode pads 210 thereon.

Referring to FIG. 2C, a circuit build-up process is performed on the carrier 20 and the semiconductor chip 21. Firstly, a dielectric layer 23 is formed on the carrier 20 and the semiconductor chip 21, and the material of the dielectric layer 23 can fill into the gap between the cavity 200 of the carrier 20 and the semiconductor chip 21. The dielectric layer 23 can be made of a photosensitive or non-photosensitive material such as PI (polyimide), ABF (Ajinomoto build-up film), PTFE (polytetrafluoroethylene), LCP (liquid crystal polymer), BCB (benzene cyclobutene) and the like.

Referring to FIG. 2D, a plurality of vias 230 are formed in the dielectric layer 23 (for example by a laser drilling or exposure/development technique), such that the electrode pads 210 on the active surface 21a of the semiconductor chip 21 are exposed by the vias 230.

Referring to FIG. 2E, a conductive layer 24 is formed on the dielectric layer 23 and the electrode pads 210 exposed by the via 230. Then, a resist layer 25 is applied on the conductive layer 24, and is formed with a plurality of circuit pattern openings 250 for partly exposing the conductive layer 24 covered by the resist layer 25, wherein a portion of the circuit pattern openings 250 of the resist layer 25 corresponds to the vias 230 of the dielectric layer 23. The conductive layer 24 can be made of a metal or conductive polymer material, and serves as a current conductive path required for a subsequent electroplating process.

Referring to FIG. 2F, the electroplating process is performed to form a circuit layer 231 on a portion of the conductive layer 24 formed on the dielectric layer 23 and exposed via the circuit pattern openings 250 of the resist layer 25, and to form a plurality of conductive structures 232 on a portion of the conductive layer 24 in the vias 230 of the dielectric layer 23. Thus, the circuit layer 231 can be electrically connected to the electrode pads 210 of the semiconductor chip 21 by the conductive structures 232 in the dielectric layer 23. The conductive structures 232 can be conductive vias.

Referring to FIG. 2G, the resist layer 25 and the portion of the conductive layer 24 covered thereby are removed to expose the circuit layer 231.

Referring to FIG. 2H, a conductive adhesive layer 26 is provided and is formed with a plurality of through holes 260 at predetermined positions corresponding to the circuit layer 231 of the dielectric layer 23, wherein a conductive adhesive post 261 is formed by filling a conductive adhesive material in each of the through holes 260. The conductive adhesive layer 26 comprises an insulating layer formed with the through holes 260 therein, wherein the insulating layer can be made of such as prepreg (PP), a tape or a thermoplastic organic material, etc. The conductive adhesive material can be selected from the group consisting of solder, metal paste (such as copper paste or silver paste) and a conductive polymer, etc.

Referring to FIG. 2I, the conductive adhesive layer 26 having the conductive adhesive posts 261 is mounted on the dielectric layer 23, such that the conductive adhesive posts 261 can be electrically connected to the electrode pads 210 of the semiconductor chip 21 by the circuit layer 231 and the conductive structures 232 of the dielectric layer 23. A circuit board 27 having a plurality of conductive pads 270 on a surface thereof is provided. The circuit board 27 is mounted via the conductive adhesive layer 26 on the carrier 20 incorporated with the semiconductor chip 21. The conductive pads 270 on the surface of the circuit board 27 correspond to the conductive adhesive posts 261 of the conductive adhesive layer 26, such that the conductive pads 270 of the circuit board 27 can be electrically connected to the circuit layer 231 of the dielectric layer 23 by the conductive adhesive posts 261 of the conductive adhesive layer 26, and are further electrically connected to the electrode pads 210 of the semiconductor chip 21 by the conductive structures (conductive vias) 232 shown as FIG. 2J. By such arrangement, the electrical connection between the semiconductor chip 21 and the circuit board 27 can be established so as to form a semiconductor package structure integrated with the carrier 20, the semiconductor chip 21 and the circuit board 27 therein. This desirably simplifies the fabrication processes, shortens the time required for fabrication, and reduces defective products, as well as facilitates mass production. By the foregoing fabrication method, the conductive adhesive layer 26 is firstly attached to the dielectric layer 23 on the carrier 20 and then mounted with the circuit board 27. Alternatively, the carrier 20 incorporated with the semiconductor chip 21, the conductive adhesive layer 26 and the circuit board 27 can all be laminated as a whole simultaneously and form the same structure illustrated as FIG. 2J.

As shown in FIG. 2J, the present invention also provides a semiconductor package structure fabricated by the foregoing method, comprising a carrier 20 having at least one cavity 200 on a surface thereof; at least one semiconductor chip 21 mounted in the cavity 200 of the carrier 20 via an adhesive layer 22 and having a plurality of electrode pads 210; a dielectric layer 23 formed on the carrier 20 and the semiconductor chip 21, wherein the dielectric layer 23 comprises a circuit layer 231 formed thereon and a plurality of conductive structures 232 formed therein, such that the circuit layer 231 is electrically connected to the electrode pads 210 of the semiconductor chip 21 by the conductive structures 232; a conductive adhesive layer 26 having a plurality of conductive adhesive posts 261 and mounted on the dielectric layer 23, wherein the conductive adhesive posts 261 are electrically connected to the circuit layer 231 of the dielectric layer 23 and are also electrically connected to the electrode pads 210 of the semiconductor chip 21 by the conductive structures 232; and a circuit board 27 having a plurality of conductive pads 270 on a surface thereof and attached to the conductive adhesive layer 26, wherein the conductive pads 270 of the circuit board 27 are electrically connected to the circuit layer 231 of the dielectric layer 23 by the conductive adhesive posts 261 of the conductive adhesive layer 26, such that the circuit board 27 can be electrically connected to the semiconductor chip 21. The circuit board 27 can be a double-layer or multi-layer circuit board.

Therefore, according to the semiconductor package structure and the method for fabricating the same proposed in the present invention, at least one semiconductor chip 21 having a plurality of electrode pads 210 formed on a surface thereof is mounted in a cavity 200 of a carrier 20, such that an overall thickness of the semiconductor package can be reduced to satisfy the requirement of profile miniaturization. Then, a dielectric layer 23 is applied on the carrier 20 and the semiconductor chip 21 and is formed with vias 230. A circuit layer 231 and a plurality of conductive structure 232 are formed on a surface of the dielectric layer 23 and in the vias 230, and are electrically connected to the electrode pads 210 of the semiconductor chip 21. Subsequently, a conductive adhesive layer 26 and a circuit board 27 having a plurality of conductive pads 270 formed on a surface thereof are mounted on the dielectric layer 23, wherein the conductive pads 270 of the circuit board 27 are electrically connected to the circuit layer 231 of the dielectric layer 23 by conductive adhesive posts 261 formed in the conductive adhesive layer 26, such that the circuit board 27 can be electrically connected to the semiconductor chip 21 so as to form a semiconductor package structure integrated with the carrier 20, the semiconductor chip 21 and the circuit board 27 therein. As a result, the drawback in the prior art such as a loss to the yield caused by multiple performances of a build-up process can be avoided, and the time required for fabrication can be shortened. The present invention combines chip carrier manufacture and a semiconductor packaging technique, and provides more flexibility to satisfy clients' requirements, as well as simplifies the semiconductor fabrication processes and an interface integration problem.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A method for fabricating a semiconductor package structure, comprising the steps of:
providing a carrier having at least one cavity on a surface thereof;
mounting at least one semiconductor chip in the cavity of the carrier, the semiconductor chip having a plurality of electrode pads;
applying a dielectric layer on the carrier and the semiconductor chip, and filling the material of the dielectric layer into the gap between the cavity of the carrier and the semiconductor chip;
forming a plurality of vias in the dielectric layer;
forming a circuit layer and a plurality of conductive structures on a surface of the dielectric layer and in the vias, wherein the circuit layer and the conductive structures are electrically connected to the electrode pads of the semiconductor chip; and
providing a conductive adhesive layer having a plurality of conductive adhesive posts, and a circuit board having a plurality of conductive pads on a surface thereof, and simultaneously mounting the circuit board and the conductive adhesive layer on the carrier, such that the conductive pads of the circuit board are electrically connected to the electrode pads of the semiconductor chip by the conductive adhesive posts of the conductive adhesive layer.

2. The method of claim 1, wherein the circuit board is mounted on the carrier via the conductive adhesive layer, and the conductive pads of the circuit board are electrically connected to the circuit layer and the conductive structures of the dielectric layer by the conductive adhesive posts of the conductive adhesive layer and are further electrically connected to the electrode pads of the semiconductor chip.

3. The method of claim 1, wherein the conductive adhesive layer is formed by the steps of:
providing an insulating layer formed with a plurality of through holes therein; and
filling a conductive adhesive material in the through holes.

4. The method of claim 3, wherein the conductive adhesive material is selected from the group consisting of solder, metal paste and a conductive polymer.

5. The method of claim 1, wherein the semiconductor chip is a passive component or an active component.

6. The method of claim 1, wherein the semiconductor chip is mounted in the cavity of the carrier via an adhesive layer.

7. The method of claim 1, wherein the circuit board is a double-layer or multi-layer circuit board.

8. A method for fabricating a semiconductor package structure, comprising the steps of:
providing a carrier having at least one cavity on a surface thereof;
mounting at least one semiconductor chip in the cavity of the carrier, the semiconductor chip having a plurality of electrode pads;
applying a dielectric layer on the carrier and the semiconductor chip, and filling the material of the dielectric layer into the gap between the cavity of the carrier and the semiconductor chip;
forming a plurality of vias in the dielectric layer;
forming a circuit layer and a plurality of conductive structures on a surface of the dielectric layer and in the vias, wherein the circuit layer and the conductive structures are electrically connected to the electrode pads of the semiconductor chip;
providing a conductive adhesive layer having a plurality of conductive adhesive posts, and mounting the conductive adhesive layer on the dielectric layer, wherein the conductive adhesive posts of the conductive adhesive layer are electrically connected to the electrode pads of the semiconductor chip; and
providing a circuit board having a plurality of conductive pads on a surface thereof, and mounting the circuit board on the conductive adhesive layer, such that the conductive pads of the circuit board are electrically connected to the electrode pads of the semiconductor chip by the conductive adhesive posts of the conductive adhesive layer.

9. The method of claim 8, wherein the circuit board is mounted on the dielectric layer via the conductive adhesive layer, and the conductive pads of the circuit board are electrically connected to the circuit layer and the conductive structures of the dielectric layer by the conductive adhesive posts of the conductive adhesive layer and are further electrically connected to the electrode pads of the semiconductor chip.

10. The method of claim 8, wherein the conductive adhesive layer is formed by the steps of:
providing an insulating layer formed with a plurality of through holes therein; and
filling a conductive adhesive material in the through holes.

11. The method of claim 10, wherein the conductive adhesive material is selected from the group consisting of solder, metal paste and a conductive polymer.

12. The method of claim 8, wherein the semiconductor chip is a passive component or an active component.

13. The method of claim 8, wherein the semiconductor chip is mounted in the cavity of the carrier via an adhesive layer.

14. The method of claim 8, wherein the circuit board is a double-layer or multi-layer circuit board.

15. A semiconductor package structure, comprising:
a carrier having at least one cavity on a surface thereof;
at least one semiconductor chip having a plurality of electrode pads and mounted in the cavity of the carrier;
a dielectric layer applied on the carrier and the semiconductor chip, wherein a circuit layer and a plurality of conductive structures are formed on the dielectric layer and are electrically connected to the electrode pads of the semiconductor chip;
a conductive adhesive layer mounted on the dielectric layer, wherein the conductive adhesive layer is formed with a plurality of conductive adhesive posts therein that are electrically connected to the circuit layer and the conductive structures of the dielectric layer; and
a circuit board having a plurality of conductive pads on a surface thereof and mounted on the conductive adhesive layer, wherein the conductive pads of the circuit board are electrically connected to the circuit layer and the conductive structures of the dielectric layer by the conductive adhesive posts of the conductive adhesive layer and are further electrically connected to the electrode pads of the semiconductor chip.

16. The semiconductor package structure of claim 15, wherein the semiconductor chip is mounted in the cavity of the carrier via an adhesive layer.

17. The semiconductor package structure of claim 15, wherein the circuit board is a double-layer or multi-layer circuit board.
